(19) United States
(12) Patent Application Publication
(10) Pub. No.: US 2026/0026109 A1
(43) Pub. Date: Jan. 22, 2026

(54) SEMICONDUCTOR DEVICES WITH EXTENDED BALLAST

(71) Applicant: International Business Machines Corporation, Armonk, NY (US)

(72) Inventors: Robert Gauthier, Williston, VT (US); Anthony I-Chih Chou, Guilderland, NY (US)

(21) Appl. No.: 18/773,666

(22) Filed: Jul. 16, 2024

(51) Int. Cl. H01L 27/02; H01L 27/088; H01L 29/06; H01L 29/423; H01L 29/775; H01L 29/786

(52) U.S. Cl. CPC H10D 89/931; H10D 84/83; H10D 30/43; H10D 30/6735; H10D 30/6757; H10D 62/121

(57) ABSTRACT

A semiconductor device is provided and includes a device finger including field effect transistors (FETs) or bipolar junctions arrayed along a substrate and one or more implanted ballasting elements. Each of the one or more implanted ballasting elements contacts a collector or an emitter of one of the FETs or the bipolar junctions and extends substantially horizontally from the collector or the emitter of the one of the FETs or the bipolar junctions and through the substrate.

### BACKGROUND

The present disclosure generally relates to fabrication methods and resulting structures for semiconductor devices. More specifically, the present disclosure relates to electrostatic discharge (ESD) nanosheet structures and ESD bipolar junction structures with extended ballasts.

A field-effect transistor (FET), such as a metal-oxide-semiconductor (MOS) FET (MOSFET), is a four-terminal device that includes a source terminal, a drain terminal, a body/well terminal and a gate terminal and uses electric fields to control current flowing through the device. An FET typically includes a semiconductor channel material, a source region and a drain region provided in the channel material, and a gate stack (also referred to as “gate”) that includes at least a gate electrode material and may also include a gate dielectric material. The gate stack is provided over a portion of the channel material between the source and the drain regions.

Recently, FETs with non-planar architectures, such as FinFETs (also sometimes referred to as “wrap around gate transistors” or “tri-gate transistors”) and nanosheet or nanoribbon FETs (also sometimes referred to as “all-around gate transistors”), have been extensively explored as alternatives to transistors with planar architectures.

### SUMMARY

According to an aspect of the disclosure, a semiconductor device is provided and includes a device finger including field effect transistors (FETs) or bipolar junctions arrayed along a substrate and one or more implanted ballasting elements. Each of the one or more implanted ballasting elements contacts a collector or an emitter of one of the FETs or the bipolar junctions and extends substantially horizontally from the collector or the emitter of the one of the FETs or the bipolar junctions and through the substrate. In one or more additional or alternative embodiments, the horizontal extension of each of the one or more implanted ballasting elements provides for increased ballast resistance as compared to structures with only vertical ballasts.

According to an aspect of the disclosure, a semiconductor device is provided and includes a substrate, field effect transistors (FETs) arrayed along a width dimension of the substrate, each of the FETs including source/drain (S/D) regions and a channel region extending between the S/D regions in a length dimension of the substrate perpendicular to the width dimension and one or more implanted ballasting elements. Each of the one or more implanted ballasting elements is disposed in contact with one of the S/D regions of one of the FETs and is configured to extend substantially horizontally from the one of the S/D regions of the one of the FETs and through the substrate in the width dimension. In one or more additional or alternative embodiments, the horizontal extension of each of the one or more implanted ballasting elements provides for increased ballast resistance as compared to structures with only vertical ballasts.

According to an aspect of the disclosure, an electrostatic discharge (ESD) nanosheet field effect transistor (NFET) device is provided and includes a lower substrate doped with a first dopant, an upper substrate including a central well doped with the first dopant and first and second wells sandwiching the central well and doped with a second dopant, NFETs arrayed along a width dimension of the upper substrate over the central well, each NFET including source/drain (S/D) regions and a channel region extending between the S/D regions in a length dimension of the substrate perpendicular to the width dimension and an implanted ballasting element disposed in contact with corresponding S/D regions of the NFETs and configured to extend substantially horizontally between the corresponding S/D regions of the NFETs and through the substrate in the width dimension. In one or more additional or alternative embodiments, the horizontal extension of each of the one or more implanted ballasting elements provides for increased ballast resistance as compared to structures with only vertical ballasts.

Additional technical features and benefits are realized through the techniques of the present disclosure. Embodiments and aspects of the disclosure are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the disclosure are apparent from the following detailed description taken in conjunction with the accompanying drawings in which:

FIG. 1 is a side view of a semiconductor device including an implanted ballasting element in accordance with embodiments;

FIG. 2 is a schematic side view of a portion of a semiconductor device in which an implanted ballasting element extends below and around shallow trench isolation (STI) in accordance with embodiments; and

FIG. 3 is a graphical illustration of rates of voltage and current increases in the semiconductor device of FIG. 1 in accordance with embodiments.

The diagrams depicted herein are illustrative. There can be many variations to the diagram or the operations described therein without departing from the spirit of the disclosure. For instance, the actions can be performed in a differing order or actions can be added, deleted or modified. Also, the term “coupled” and variations thereof describes having a communications path between two elements and does not imply a direct connection between the elements with no intervening elements/connections between them. All of these variations are considered a part of the specification.

In the accompanying figures and following detailed description of the described embodiments, the various elements illustrated in the figures are provided with two or three digit reference numbers. With minor exceptions, the leftmost digit(s) of each reference number correspond to the figure in which its element is first illustrated.

### DETAILED DESCRIPTION

According to an aspect of the disclosure, a semiconductor device is provided and includes a device finger including field effect transistors (FETs) or bipolar junctions arrayed along a substrate and one or more implanted ballasting elements. Each of the one or more implanted ballasting elements contacts a collector or an emitter of one of the FETs or the bipolar junctions and extends substantially horizontally from the collector or the emitter of the one of the FETs or the bipolar junctions and through the substrate. In one or more additional or alternative embodiments, the horizontal extension of each of the one or more implanted ballasting elements provides for increased ballast resistance as compared to structures with only vertical ballasts.

In accordance with one or more additional or alternative embodiments, the semiconductor device includes multiple device fingers and the one or more implanted ballasting elements enables substantially uniform current flow across the device finger and each of the multiple device fingers so that turn-on of all of the multiple device fingers is enabled.

In accordance with one or more additional or alternative embodiments, for the one of the FETs or the bipolar junctions, rates of positive voltage increases exceed rates of current increases so that turn-on of all of the multiple device fingers is enabled and to give much higher failure currents and reduce overall ESD device size.

According to an aspect of the disclosure, a semiconductor device is provided and includes a substrate, field effect transistors (FETs) arrayed along a width dimension of the substrate, each of the FETs including source/drain (S/D) regions and a channel region extending between the S/D regions in a length dimension of the substrate perpendicular to the width dimension and one or more implanted ballasting elements. Each of the one or more implanted ballasting elements is disposed in contact with one of the S/D regions of one of the FETs and is configured to extend substantially horizontally from the one of the S/D regions of the one of the FETs and through the substrate in the width dimension. In one or more additional or alternative embodiments, the horizontal extension of each of the one or more implanted ballasting elements provides for increased ballast resistance as compared to structures with only vertical ballasts.

In accordance with one or more additional or alternative embodiments, the FETs form a device finger, the semiconductor device includes multiple device fingers and the one or more implanted ballasting elements enables substantially uniform current flow across the device finger and each of the multiple device fingers so that turn-on of all of the multiple device fingers is enabled.

In accordance with one or more additional or alternative embodiments, for the one of the FETs, rates of positive voltage increases exceed rates of current increases so that turn-on of all of the multiple device fingers is enabled and to give much higher failure currents and reduce overall ESD device size.

In accordance with one or more additional or alternative embodiments, the semiconductor device is configured as a shallow trench isolation (STI)-bound lateral NPN or PNP device and the one of the S/D regions of the one of the FETs is provided as one or both of an emitter and a collector so that these types of semiconductor devices can be provided with increased ballast resistance as compared to similar structures with only vertical ballasts.

In accordance with one or more additional or alternative embodiments, the semiconductor device is configured as a non-self-aligned and non-shallow trench isolation (STI)-bound lateral NPN or PNP device and the one of the S/D regions of the one of the FETs is provided as one or both of an emitter and a collector so that these types of semiconductor devices can be provided with increased ballast resistance as compared to similar structures with only vertical ballasts.

In accordance with one or more additional or alternative embodiments, wherein the FETs are nanosheet FETs (NFETs) so that these types of semiconductor devices can be provided with increased ballast resistance as compared to similar structures with only vertical ballasts.

In accordance with one or more additional or alternative embodiments, the one or more implanted ballasting elements extends from the one of the S/D regions of the one of the FETs to a corresponding one of the S/D regions of a neighboring one of the FETs to provide for the horizontal extension of the one or more implanted ballasting elements.

In accordance with one or more additional or alternative embodiments, the one or more implanted ballasting elements extends from the one of the S/D regions of the one of the FETs to a corresponding one of the S/D regions of another one of the FETs to provide for the horizontal extension of the one or more implanted ballasting elements.

In accordance with one or more additional or alternative embodiments, the semiconductor device further includes shallow trench isolation (STI) disposed in the substrate to bound the FETs which can either bound the one or more implanted ballasting elements as well or the one or more implanted ballasting elements can extend below the STI.

In accordance with one or more additional or alternative embodiments, the implanted ballasting element extends below and around the STI to a corresponding one of the S/D regions of another one of the FETs to provide for further increased ballasting resistance.

According to an aspect of the disclosure, an electrostatic discharge (ESD) nanosheet field effect transistor (NFET) device is provided and includes a lower substrate doped with a first dopant, an upper substrate including a central well doped with the first dopant and first and second wells sandwiching the central well and doped with a second dopant, NFETs arrayed along a width dimension of the upper substrate over the central well, each NFET including source/drain (S/D) regions and a channel region extending between the S/D regions in a length dimension of the substrate perpendicular to the width dimension and an implanted ballasting element disposed in contact with corresponding S/D regions of the NFETs and configured to extend substantially horizontally between the corresponding S/D regions of the NFETs and through the substrate in the width dimension. In one or more additional or alternative embodiments, the horizontal extension of each of the one or more implanted ballasting elements provides for increased ballast resistance as compared to structures with only vertical ballasts.

In accordance with one or more additional or alternative embodiments, the NFETs form a device finger, the ESD NFET device includes multiple device fingers and the implanted ballasting element enables substantially uniform current flow across the device finger and each of the multiple device fingers so that turn-on of all of the multiple device fingers is enabled.

In accordance with one or more additional or alternative embodiments, rates of positive voltage increases of the NFETs exceed rates of current increases so that turn-on of all of the multiple device fingers is enabled and to give much higher failure currents and reduce overall ESD device size.

In accordance with one or more additional or alternative embodiments, the lower substrate and the central well are p-doped and the first and second wells are n-doped to be compliant with lithographic and complementary-metal-oxide-semiconductor (CMOS) processing.

In accordance with one or more additional or alternative embodiments, the lower substrate and the central well are n-doped and the first and second wells are p-doped to be compliant with lithographic and complementary-metal-oxide-semiconductor (CMOS) processing.

In accordance with one or more additional or alternative embodiments, shallow trench isolation (STI) is provided to bound the NFETs, wherein the lower substrate and the central well are p-doped and the first and second wells are n-doped, where the STI can either bound the one or more implanted ballasting elements as well or the one or more implanted ballasting elements can extend below the STI.

In accordance with one or more additional or alternative embodiments, shallow trench isolation (STI) is provided to bound the NFETs, wherein the lower substrate and the central well are n-doped and the first and second wells are p-doped, where the STI can either bound the one or more implanted ballasting elements as well or the one or more implanted ballasting elements can extend below the STI.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Turning now to an overview of technologies that are more specifically relevant to aspects of the disclosure, conventional semiconductor devices can be provided as FETs with source and drain regions pulled relatively far from the gate. In recent semiconductor devices that require strict and tight device pitches and have limited area on which to build devices, this is not possible and source and drain regions are required to be positioned much more closely to their respective gates.

Typical ESD devices will have hundreds of fingers in parallel (i.e., in a matrix of columns and rows). For such ESD devices, particularly those provided as FET structures and lateral bipolar structures, it is often important to have ballasting resistance integrated into drain (i.e., collector) regions and source (i.e., emitter) regions to enable good current uniformity in each finger. This can be difficult to achieve, however, given the need to position source and drain regions close to their respective gates.

Proper ballasting resistance enables all of the fingers of an ESD device to turn-on at nearly the same times which, in turn, leads to much higher failure currents and reduced overall ESD device size requirements. Conversely, without proper ballasting resistance, only one or two fingers only might turn on ahead of the others due to process variability, for example. In these cases, failure voltages in the one or two fingers are reached before the other fingers are able to turn on.

Turning now to an overview of the aspects of the disclosure, one or more embodiments of the disclosure address the above-described shortcomings of the prior art by providing a semiconductor device including a substrate, a device finger that includes FETs or bipolar junctions arrayed along the substrate and one or more implanted ballasting elements. Each of the one or more implanted ballasting elements is disposed in contact with a collector or an emitter of one of the FETs or the bipolar junctions and is configured to extend substantially horizontally from the collector or the emitter of the one of the FETs or the bipolar junctions and through the substrate. In addition, a semiconductor device is provided and includes a substrate, FETs arrayed along a width dimension of the substrate and one or more implanted ballasting elements. Each of the FETs includes source/drain (S/D) regions and a channel region extending between the S/D regions in a length dimension of the substrate perpendicular to the width dimension. Each of the one or more implanted ballasting elements is disposed in contact with one of the S/D regions of one of the FETs and is configured to extend substantially horizontally from the one of the S/D regions of the one of the FETs and through the substrate in the width dimension.

The above-described aspects of the disclosure address the shortcomings of the prior art by providing a semiconductor device that includes a junction with an extended implanted ballast region by which two S/D epitaxial regions are connected together. The implanted ballast region can be extended as much as needed to add more or less ballast resistance.

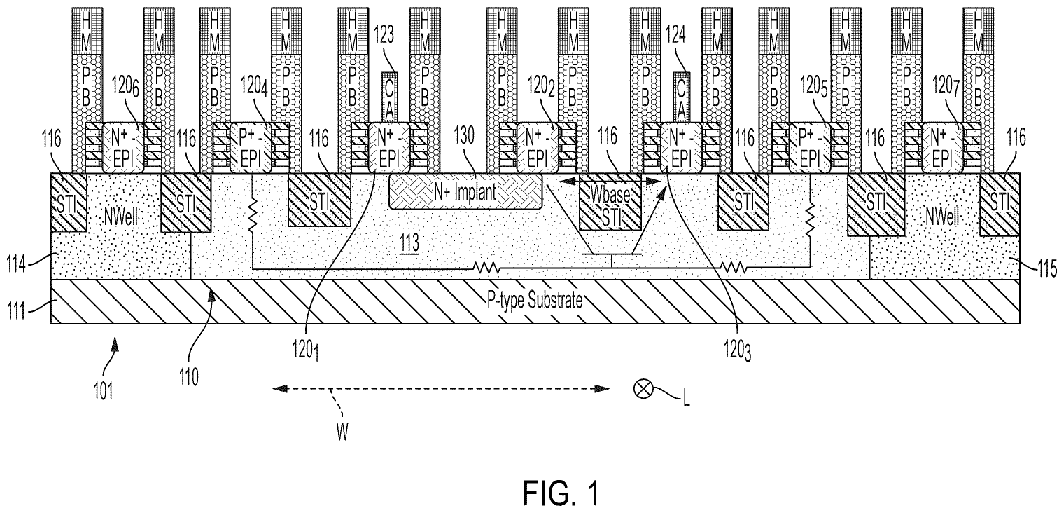

With reference to FIG. 1, a semiconductor device 101 is provided and includes a substrate 110, FETs 120₁₋₇ arrayed along a width dimension W of the substrate 110 and one or more implanted ballasting elements 130 for provided ballast resistance. The substrate 110 can include a lower substrate 111 that is doped with a first dopant and an upper substrate 112. The upper substrate 112 includes a central well 113 doped with the first dopant, a first well 114 and a second well 115. The first well 114 and the second well 115 sandwich the central well 113 and are each doped with a second dopant. In accordance with embodiments, the first dopant can be a p-dopant and the second dopant can be an n-dopant or, alternatively, the first dopant can be an n-dopant and the second dopant can be a p-dopant. In either case, the semiconductor device 101 further includes STI 116 arrayed in the upper substrate 112 to bound the FETs 120₁₋₇.

For purposes of clarity and brevity, the following description (and FIG. 1) will relate to the embodiments in which the lower substrate 111 is p-doped, the central well 113 is p-doped, the first well 114 is n-doped, the second well 115 is n-doped and the semiconductor device 101 includes the STI 116. It is to be understood, however, that other embodiments exist and would be readily available to persons of ordinary skill in the art without undue experimentation. That is, the semiconductor device 101 can be configured as a shallow trench isolation (STI)-bound lateral NPN or PNP device and/or as a non-self-aligned and non-shallow trench isolation (STI)-bound lateral NPN or PNP device.

With continued reference to FIG. 1, each of the FETs 120₁₋₇ can be provided as a nanosheet FET (NFET) that includes S/D regions 121 and a channel region (i.e., nanosheet channel regions) 122 extending between the S/D regions 121 in a length dimension L of the substrate 110, which is perpendicular to the width dimension W. In greater detail, as shown in FIG. 1, the FETs 120₁₋₇ can include drain/collector FETs 120₁ and 120₂, a source/emitter FET 120₃, p-well contact FETs 120₄ and 120₅ and n-well ground FETs 120₆ and 120₇. In these or other cases, the p-well contact FETs 120₄ and 120₅ are provided on opposite ends of the central well 113 and are connected through the central well 113 to form a transistor base, the drain/collector FETs 120₁ and 120₂ and the source/emitter FET 120₃ are provided on the central well 113 between the p-well contact FETs 120₄ and 120₅ and the n-well ground FETs 120₆ and 120₇ are provided on the first well 114 and the second well 115, respectively. Contacts 123 and 124 can be disposed on drain/collector FET 120₁ and on source/emitter FET 120₃, respectively.

Each of the one or more implanted ballasting elements 130 can be disposed in contact with one of the S/D regions 121 of one of the FETs 120₁₋₇ and can be configured to extend substantially horizontally from the one of the S/D regions 121 of the one of the FETs 120₁₋₇ and through the substrate 110 in the width dimension W. In greater detail, as shown in FIG. 1, the illustrated implanted ballasting element 130 is disposed in contact at opposite ends thereof with the neighboring drain/collector FETs 120₁ and 120₂ (a similar implanted ballasting element 130 can be disposed in contact with the source/emitter FET 120₃, for example).

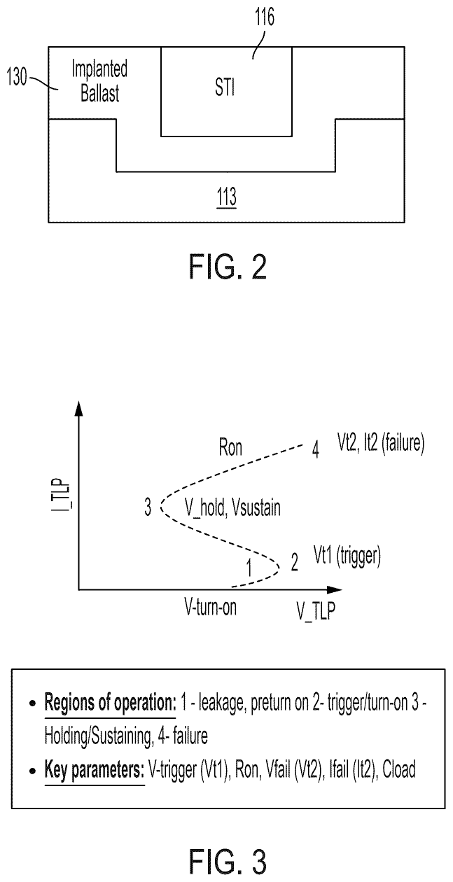

With reference to FIG. 2 and in accordance with embodiments, the one or more implanted ballasting elements 130 can extend below and around the STI 116. In these or other cases, where the FETs 120₁₋₇ are bound by the STI 116, a horizontal length of the one or more implanted ballasting elements 130 may not be limited by a presence of STI 116. Thus, in cases in which additional ballasting resistance is needed above and beyond what can be provided by the illustrated implanted ballasting element 130 of FIG. 1, in particular, the one or more implanted ballasting elements 130 of FIG. 2 can be provided.

With reference to FIG. 3 and in accordance with embodiments, the FETs 120₁₋₇ can form a device finger 102 and the semiconductor device 101 can include multiple device fingers of similar configuration and construction. In these or other cases, the one or more implanted ballasting elements 130 effectively enable substantially uniform current flow across the device finger 120 and across each of the multiple device fingers also included in the semiconductor device 101. This advantage arises from the fact that the one or more implanted ballasting elements 130 provide for increased ballasting resistance for the semiconductor device 101 whereby rates Ron of positive voltage increases of the drain/collector FETs 120₁ and 120₂ of FIG. 1 exceed rates of current increases as shown in FIG. 3.

Various embodiments of the present disclosure are described herein with reference to the related drawings. Alternative embodiments can be devised without departing from the scope of this disclosure. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

Spatially relative terms, e.g., “beneath,” “below,” “lower,” “above,” “upper,” and the like, can be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device can be otherwise oriented (rotated 90 degrees or at other orientations) and the spatially relative descriptors used herein interpreted accordingly.

The phrase “selective to,” such as, for example, “a first element selective to a second element,” means that the first element can be etched and the second element can act as an etch stop.

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The term “conformal” (e.g., a conformal layer) means that the thickness of the layer is substantially the same on all surfaces, or that the thickness variation is less than 15% of the nominal thickness of the layer.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. For example, an epitaxially grown semiconductor material deposited on a {100} orientated crystalline surface can take on a {100} orientation. In some embodiments of the disclosure, epitaxial growth and/or deposition processes can be selective to forming on semiconductor surface, and cannot deposit material on exposed surfaces, such as silicon dioxide or silicon nitride surfaces.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present disclosure will now be provided. Although specific fabrication operations used in implementing one or more embodiments of the present disclosure can be individually known, the described combination of operations and/or resulting structures of the present disclosure are unique. Thus, the unique combination of the operations described in connection with the fabrication of a semiconductor device according to the present disclosure utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The flowchart and block diagrams in the Figures illustrate possible implementations of fabrication and/or operation methods according to various embodiments of the present disclosure. Various functions/operations of the method are represented in the flow diagram by blocks. In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved.

The descriptions of the various embodiments of the present disclosure have been presented for purposes of illustration, but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A semiconductor device, comprising:
a device finger comprising field effect transistors (FETs) or bipolar junctions arrayed along a substrate; and
one or more implanted ballasting elements,
each of the one or more implanted ballasting elements contacting a collector or an emitter of one of the FETs or the bipolar junctions and extending substantially horizontally from the collector or the emitter of the one of the FETs or the bipolar junctions and through the substrate.

2. The semiconductor device according to claim 1, wherein:
the semiconductor device comprises multiple device fingers, and
the one or more implanted ballasting elements enables substantially uniform current flow across the device finger and each of the multiple device fingers.

3. The semiconductor device according to claim 1, wherein, for the one of the FETs or the bipolar junctions, rates of positive voltage increases exceed rates of current increases.

4. A semiconductor device, comprising:
a substrate;
field effect transistors (FETs) arrayed along a width dimension of the substrate, each of the FETs comprising source/drain (S/D) regions and a channel region extending between the S/D regions in a length dimension of the substrate perpendicular to the width dimension; and
one or more implanted ballasting elements, each of the one or more implanted ballasting elements being disposed in contact with one of the S/D regions of one of the FETs and configured to extend substantially horizontally from the one of the S/D regions of the one of the FETs and through the substrate in the width dimension.

5. The semiconductor device according to claim 4, wherein:
the FETs form a device finger,
the semiconductor device comprises multiple device fingers, and
the one or more implanted ballasting elements enables substantially uniform current flow across the device finger and each of the multiple device fingers.

6. The semiconductor device according to claim 4, wherein, for the one of the FETs, rates of positive voltage increases exceed rates of current increases.

7. The semiconductor device according to claim 4, wherein:
the semiconductor device is configured as a shallow trench isolation (STI)-bound lateral NPN or PNP device, and
the one of the S/D regions of the one of the FETs is provided as one or both of an emitter and a collector.

8. The semiconductor device according to claim 4, wherein:
the semiconductor device is configured as a non-self-aligned and non-shallow trench isolation (STI)-bound lateral NPN or PNP device, and
the one of the S/D regions of the one of the FETs is provided as one or both of an emitter and a collector.

9. The semiconductor device according to claim 4, wherein the FETs are nanosheet FETs (NFETs).

10. The semiconductor device according to claim 4, wherein the one or more implanted ballasting elements extends from the one of the S/D regions of the one of the FETs to a corresponding one of the S/D regions of a neighboring one of the FETs.

11. The semiconductor device according to claim 4, wherein the one or more implanted ballasting elements extends from the one of the S/D regions of the one of the FETs to a corresponding one of the S/D regions of another one of the FETs.

12. The semiconductor device according to claim 4, wherein the semiconductor device further comprises shallow trench isolation (STI) disposed in the substrate to bound the FETs.

13. The semiconductor device according to claim 12, wherein the implanted ballasting element extends below and around the STI to a corresponding one of the S/D regions of another one of the FETs.

14. An electrostatic discharge (ESD) nanosheet field effect transistor (NFET) device, comprising:
a lower substrate doped with a first dopant;
an upper substrate comprising a central well doped with the first dopant and first and second wells sandwiching the central well and doped with a second dopant;
NFETs arrayed along a width dimension of the upper substrate over the central well, each NFET comprising source/drain (S/D) regions and a channel region extending between the S/D regions in a length dimension of the substrate perpendicular to the width dimension; and
an implanted ballasting element disposed in contact with corresponding S/D regions of the NFETs and configured to extend substantially horizontally between the corresponding S/D regions of the NFETs and through the substrate in the width dimension.

15. The ESD NFET device according to claim 14, wherein:
the NFETs form a device finger,
the ESD NFET device comprises multiple device fingers, and
the implanted ballasting element enables substantially uniform current flow across the device finger and each of the multiple device fingers.

16. The ESD NFET device according to claim 14, wherein rates of positive voltage increases of the NFETs exceed rates of current increases.

17. The ESD NFET device according to claim 14, wherein the lower substrate and the central well are p-doped and the first and second wells are n-doped.

18. The ESD NFET device according to claim 14, wherein the lower substrate and the central well are n-doped and the first and second wells are p-doped.

19. The ESD NFET device according to claim 14, further comprising shallow trench isolation (STI) to bound the NFETs, wherein the lower substrate and the central well are p-doped and the first and second wells are n-doped.

20. The ESD NFET device according to claim 14, further comprising shallow trench isolation (STI) to bound the NFETs, wherein the lower substrate and the central well are n-doped and the first and second wells are p-doped.
